(19) United States
(12) Patent Application Publication
(10) Pub. No.: US 2025/0391691 A1
(43) Pub. Date: Dec. 25, 2025

(54) DIELECTRIC BOND LAYER FOR JOINING OF DISSIMILAR CERAMIC SEGMENTS OF A SUBSTRATE SUPPORT

(71) Applicant: Applied Materials, Inc., Santa Clara, CA (US)

(72) Inventors: Amir H. TAVAKOLI, San Jose, CA (US); Jian LI, Fremont, CA (US)

(21) Appl. No.: 18/749,204

(22) Filed: Jun. 20, 2024

(51) Int. Cl. H01L 21/683; C23C 16/458; H01L 21/687

(52) U.S. Cl. CPC H01L 21/6833; C23C 16/4585; H01L 21/68757; H01L 21/68785

(57) ABSTRACT

The present disclosure generally provides substrate supports for disposition in processing chambers and methods of forming thereof. The substrate supports include a body having a top segment that includes an oxide composition and a lower segment that includes a nitride composition. One or more chucking electrodes are embedded in the top segment. A mesh is embedded in the lower segment. One or more heating elements are disposed below the mesh, proximal to the support shaft. A bond layer is disposed between the top segment and the lower segment.

### BACKGROUND

### FIELD

Embodiments of the present disclosure generally relate to substrate supports including electrostatic chucks, and related apparatus, methods, and processing chambers (e.g., semiconductor processing chambers).

### DESCRIPTION OF THE RELATED ART

Various semiconductor processing techniques implement one or more ceramic components that are subject to harsh chemical conductions during plasma processing techniques at temperatures of greater than 400 °C. For example, functional ceramic components (e.g., electrostatic chucks and heaters) can be subject to wafer processing or chamber cleaning techniques using CF₄ or NF₃ plasma chemistries. Conventional dielectric ceramic components used for high temperature wafer chucking through Johnson-Rahbek (J-R) effects are formed by a bulk material including undoped or doped aluminum nitride dielectrics. Unfortunately, proper functioning of the aluminum nitride dielectrics is limited to temperatures of less than 700 °C, due to inadequate electrical resistivity for maintaining a substrate on the ceramic component, via a clamping force. Moreover, even at lower temperatures the aluminum nitride dielectrics can degrade due the inherent low chemical resistance of the material to fluorination.

Conventional approaches to prevent degradation of ceramic components in processing chambers have focused on providing a fluorine resistant coating. Unfortunately, the fluorine resistant coatings can crack and/or delaminate during processing due to dissimilar thermomechanical properties, which can lead to particle contamination during substrate processing. Moreover, the cracking and/or delamination of the fluorine resistant coating requires complex regeneration processes to correct the cracks, thereby increasing downtime and manufacturing costs.

Accordingly, there is a need for improved substrate supports.

### SUMMARY

Embodiments of the present disclosure generally relate to substrate supports including electrostatic chucks, and related apparatus, methods, and processing chambers (e.g., semiconductor processing chambers).

In one or more embodiments, the present disclosure generally provides substrate supports for disposition in processing chambers. The substrate supports include a body having a top segment that includes an oxide composition and a lower segment that includes a nitride composition. One or more chucking electrodes are embedded in the top segment. A mesh is embedded in the lower segment. One or more heating elements are disposed below the mesh, proximal to the support shaft. A bond layer is disposed between the top segment and the lower segment.

In one or more embodiments, the present disclosure also generally provides substrate supports for disposition in processing chambers. A body having a top segment includes an oxide composition and a lower segment includes a nitride composition. One or more chucking electrodes are embedded in the top segment. A mesh is embedded in the lower segment. One or more heating elements are disposed below the mesh proximal to a support shaft. A bond layer is disposed between the top segment and the lower segment, in which the bond layer includes a mixture.

In one or more embodiments, the present disclosure also generally provides methods of forming substrate supports. The method include preparing a pre-sintered bond layer that includes an oxide composition and a nitride composition. The pre-sintered bond layer is disposed between a top segment of a body of the substrate support and a lower segment of the body. The pre-sintered bond layer, the top segment of the body, and the lower segment of the body is cured.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1 is a schematic cross-sectional view of a substrate processing chamber in accordance with embodiments of the present disclosure.

FIG. 2 is a schematic cross-sectional view of a substrate support in accordance with embodiments of the present disclosure.

FIGS. 3A-3G are diagrammatic representations of an oxide composition having a binary oxide composition or a tertiary oxide composition in accordance with embodiments of the present disclosure.

FIGS. 4A-4D are diagrammatic representations of a body having a bond layer in accordance with embodiments of the present disclosure.

FIG. 5 is a flow diagram representation of a method of forming a substrate support in accordance with embodiments of the present disclosure.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to segments of a ceramic component and methods of production thereof for use as a bond layer of a ceramic component, e.g., a substrate support, heater, and/or electrostatic chuck, in a processing chamber. In some embodiments, the bond layers can include a mixture of an oxide composition and a nitride composition. In some embodiments, the oxide composition can include one or more of a binary metal oxide composition and/or a ternary metal oxide composition. In some embodiments, the nitride composition can include one or more of a binary metal nitride.

In some embodiments, substrate support with a top segment made of certain classes of oxide dielectric chemical compositions not only possess a high electrical resistivity at elevated temperatures (400 - 950°C), needed for clamping of a substrate on top of the support, but also show a promising chemical compatibility to the substrate processing and cleaning procedures using fluorine plasma chemistries. While use of the oxide dielectrics for the top segment of a substrate support can be advantageous, an undoped or doped aluminum nitride dielectric for the lower segment is usually preferred in order to take advantage of the aluminum nitride’s high thermal conductivity for a uniform substrate heating. In some embodiments, the bond layers can increase the longevity of the ceramic component, e.g., a substrate support, heater, and/or electrostatic chuck, due to the increased thermomechanical compatibility between a top segment of a substrate support and a lower segment of the substrate support, thereby reducing the delamination and/or cracking.

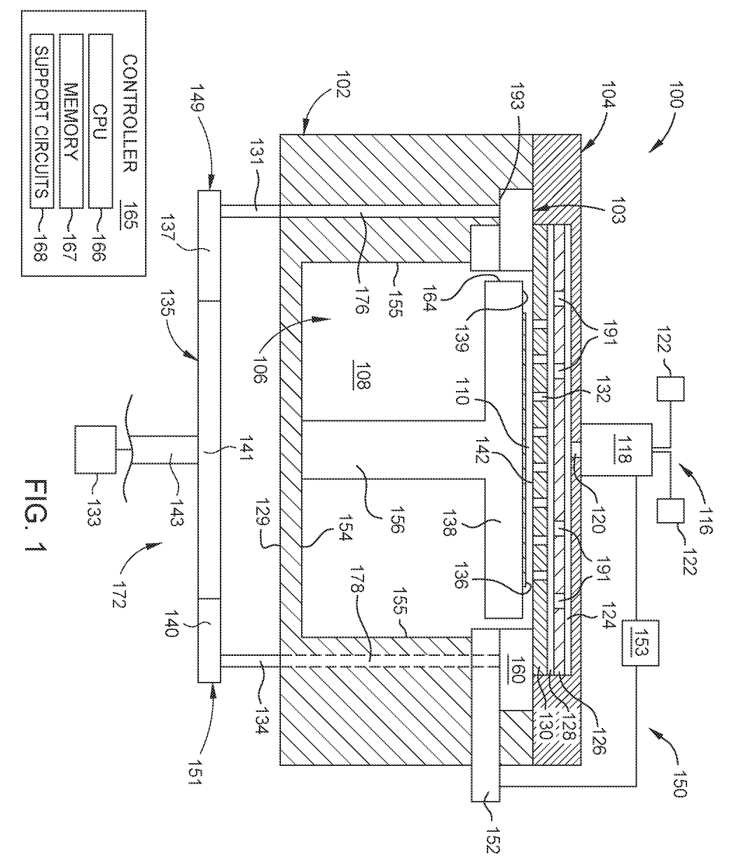

FIG. 1A is a schematic cross-sectional view of a substrate processing chamber 100, according to one implementation. The substrate processing chamber 100 may be, for example, a chemical vapor deposition (CVD) chamber or a plasma enhanced CVD chamber. The substrate processing chamber 100 has a chamber body 102 and a chamber lid 104. The chamber body 102 includes an internal volume 106 therein. The internal volume 106 is the space defined by the chamber body 102 and the chamber lid 104.

The substrate processing chamber 100 includes a gas distribution assembly 116 coupled to or disposed in the chamber lid 104 to deliver a flow of one or more gases into a processing region 110. The gas distribution assembly 116 includes a gas manifold 118 coupled to a gas inlet passage 120 formed in the chamber lid 104. The gas manifold 118 receives a flow of gases from one or more gas sources 122 (two are shown). One or more of the gas sources 122 may include a source of cleaning fluid such as a remote plasma source (RPS). During a cleaning process, the RPS may generate cleaning radicals using a reactive gas (e.g., a halogen-containing gas or oxygen-containing gas, among others). For example, fluorine-containing reactive gases such as NF₃ may be used to generate a flow of cleaning fluid containing fluorine radicals. Alternatively, oxygen gas (e.g., O₂) may be used to generate a flow of cleaning fluid containing oxygen radicals. The flow of gases received from the one or more gas sources 122 distributes across a gas box 124, flows through a plurality of openings 191 of a backing plate 126, and further distributes across a plenum 128 defined by the backing plate 126 and a faceplate 130. The faceplate 130 is disposed in the internal volume 106 between the plenum 128 and the processing region 110. The flow of gases then flows into the processing region 110 of the internal volume 106 through a plurality of openings 132 of the faceplate 130.The gases enter the processing region 110 through a lower surface 142 of the faceplate 130 which faces the processing region 110.

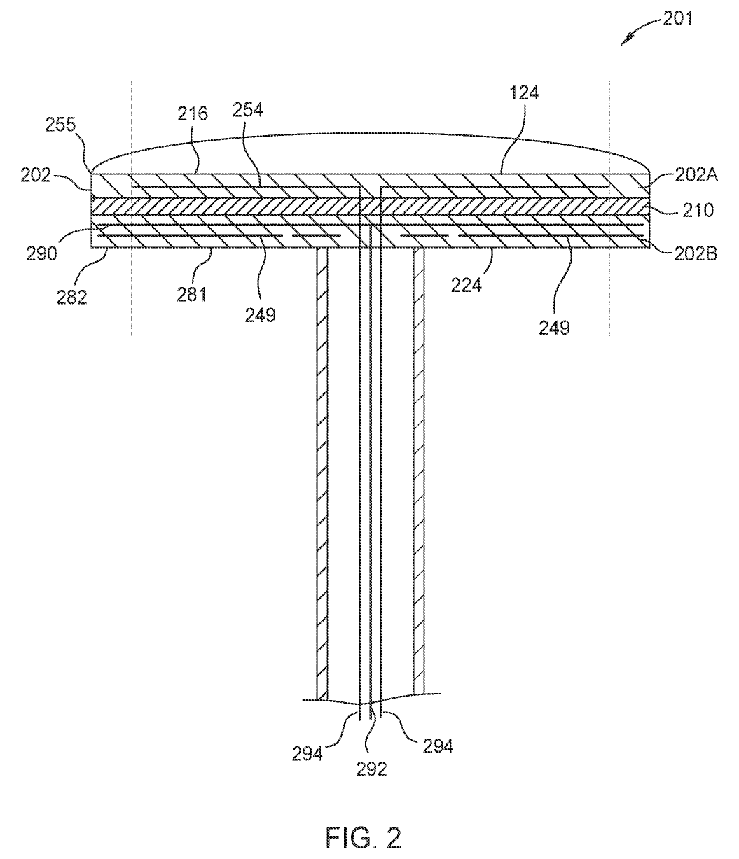

The internal volume 106 includes a substrate support 138 disposed in the chamber body 102. The substrate support 138 supports a substrate 136 within the substrate processing chamber 100. The substrate support 138 supports the substrate 136 on a support surface 139 of the substrate support 138. The substrate support 138 has a bottom neck 156. The substrate support 138 includes a heater and an electrode disposed therein, as shown below in reference to FIG. 2. The electrode may supply alternating current (AC), direct current (DC) voltage, or radio frequency (RF) energy to the internal volume 106 and/or the processing region 110.

The substrate support 138 is movably disposed in the internal volume 106 by a lift system (not shown). Movement of the substrate support 138 facilitates transfer of the substrate 136 to and from the internal volume 106 through a slit valve (not shown) formed through the chamber body 102. The substrate support 138 may also be moved to different processing positions for processing of the substrate 136.

During substrate processing, as gases flow through the plurality of openings 132 and into the processing region 110, a heater heats the substrate support 138 and the support surface 139. Also during substrate processing, the electrode in the substrate support 138 propagates the alternating current (AC), direct current (DC) voltage, or radio frequency (RF) energy to facilitate plasma generation in the processing region 110 and/or to facilitate chucking of the substrate 136 to the substrate support 138. The gases in the processing region 110, heating of the substrate support 138, and energy from the electrode in the substrate support 138 facilitate deposition of a film onto the substrate 136 during substrate processing. The faceplate 130 (which is grounded via coupling to the chamber body 102) and the electrode of the substrate support 138 facilitate formation of a capacitive plasma coupling. When power is supplied to the electrode in the substrate support 138, an electric field is generated between the faceplate 130 and substrate support 138 such that atoms of gases present in the processing region 110 between the substrate support 138 and the faceplate 130 are ionized and release electrons. The ionized atoms accelerate to the substrate support 138 to facilitate film formation on the substrate 136.

A pumping device 103 is disposed in the substrate processing chamber 100. The pumping device 103 facilitates removal of gases from the internal volume 106 and processing region 110. The gases exhausted by the pumping device 103 include one or more of a processing gas, a processing residue, a cleaning gas, a cleaning residue, and/or a purge gas. The processing residue may result from the process of depositing a film onto the substrate 136.

The pumping device 103 includes a pumping ring 160 disposed on a stepped surface 193 of the chamber body 102. The stepped surface 193 is stepped upwards from a bottom surface 154 of the chamber body 102. The stepped surface 193 supports the pumping ring 160. The pumping ring 160 includes a body 107 (shown in FIG. 1B). The body 107 of the pumping ring 160 is made from material including one or more of aluminum, aluminum oxide, and/or aluminum nitride. The pumping ring 160 is fluidly coupled to a foreline 172 through a first conduit 176 and a second conduit 178. The foreline 172 includes a first vertical conduit 131, a second vertical conduit 134, a horizontal conduit 135, and an exit conduit 143. The exit conduit 143 in one example is a third vertical conduit. In one example, the first conduit 176 and the second conduit 178 are openings formed in the chamber body 102 and extend from the stepped surface 193 to a lower outer surface 129 of the chamber body 102. Alternatively, the first conduit 176 and the second conduit 178 may be tubes or other flow devices that extend between a surface of the chamber body 102, such as the bottom surface 154, and the pumping ring 160. As an example, the first conduit 176 and the second conduit 178 may be part of the first vertical conduit 131 and the second vertical conduit 134, respectively. In such an example, the first vertical conduit 131 and the second vertical conduit 134 may extend through the chamber body 102 and be coupled to the pumping ring 160.

The first conduit 176 is fluidly coupled to the pumping ring 160 at a first end and the first vertical conduit 131 of the foreline 172 at a second end. The second conduit 178 is fluidly coupled to the pumping ring 160 at a first end and the second vertical conduit 134 of the foreline 172 at a second end. The first vertical conduit 131 and the second vertical conduit 134 are fluidly coupled to the horizontal conduit 135. The horizontal conduit 135 includes a first portion 137 coupled to the first vertical conduit 131, a second portion 140 coupled to the second vertical conduit 134, and a third portion 141 coupled to the exit conduit 143. The horizontal conduit 135 includes a first end 149 adjacent to the first vertical conduit 131 and a second end 151 adjacent to the second vertical conduit 134. The horizontal conduit 135 may be made up of a single body or fabricated from two or more components.

The first conduit 176, second conduit 178, first vertical conduit 131, second vertical conduit 134, and horizontal conduit 135 are configured to direct gases therethrough. The first conduit 176, second conduit 178, first vertical conduit 131 and second vertical conduit 134 need not be completely vertical and may be angled or may include one or more bends and/or angles. The horizontal conduit 135 need not be completely horizontal and may be angled or may include one or more bends and/or angles.

In one embodiment, which can be combined with other embodiments, the pumping ring 160 is disposed inside of the chamber body 102 while the first vertical conduit 131, the second vertical conduit 134, the horizontal conduit 135, and the exit conduit 143 are disposed or extend outside of the chamber body 102. In such an embodiment, the first conduit 176 and the second conduit 178 are disposed through the chamber body 102.

The exit conduit 143 is fluidly coupled to a vacuum pump 133 to control the pressure within the processing region 110 and to exhaust gases and residue from the processing region 110. The vacuum pump 133 exhausts gases from the processing region 110 through the pumping ring 160, the first conduit 176, the second conduit 178, the first vertical conduit 131, the second vertical conduit 134, the horizontal conduit 135, and the exit conduit 143 of the foreline 172.

A cleaning assembly 150 is coupled to the substrate processing chamber 100. The manifold 118 and/or one or more gas sources 122 may form part of the cleaning assembly 150. The cleaning assembly 150 diverts at least a portion of a flow of cleaning fluid from the manifold 118 to a sidewall 155 of the chamber body 102. The cleaning assembly 150 generally includes a distribution ring for introducing the cleaning fluid to the internal volume 106 through the sidewall 155 of the chamber body 102 and an isolation valve 153 regulating flow of cleaning fluid from the manifold 118 to the distribution ring. The distribution ring is disposed in the chamber body 102 adjacent to and/or below the pumping ring 160. The flow of cleaning fluid exiting the distribution ring may be directed primarily through a lower portion 108 of the internal volume 106 including along the bottom surface 154 and the sidewall 155 of the chamber body 102 before being exhausted through the pumping ring 160. The lower portion 108 of the internal volume 106 may refer to a region defined vertically between the bottom surface 154 and the pumping ring 160 and defined laterally between opposing sidewalls 155 of the chamber body 102. The cleaning fluid and radicals contained in the lower portion 108 of the internal volume 106 may contact and clean surfaces inside the substrate processing chamber 100 located below the faceplate 130 such as the bottom neck 156 of the substrate support 138, substrate support edge 164, sidewalls 155, and pumping ring 160.

In one embodiment (not shown), which can be combined with other embodiments, the cleaning fluid may contact and clean an edge of the faceplate 130. For example, processing residue may accumulate along an outer edge region of the lower surface 142 of the faceplate 130 located proximate an interface between the faceplate 130 and an inner radial wall of at least one of the pumping ring or insulator ring as described in more detail below. In such examples, upward flow of cleaning fluid from the lower portion 108 of the internal volume 106 to the pumping ring 160 may facilitate cleaning of the faceplate edge, unlike conventional approaches in which cleaning flow does not contact the faceplate edge. The cleaning assembly 150 is described in more detail below with regard to FIG. 1B.

A controller 165, such as a programmable computer, is connected to the substrate processing chamber 100 and the cleaning assembly 150. For example, the controller 165 may be connected to the lift system of the substrate support 138 for directing movement of the substrate support 138 to different processing positions as shown in FIGS. 2A-2D. The controller 165 may be connected to the isolation valve 153 for opening and closing the isolation valve 153 to regulate flow of cleaning fluid from the manifold 118 to the distribution ring. The controller 165 may be connected to various other components of the substrate processing chamber 100 and the cleaning assembly 150.

The controller 165 includes a programmable central processing unit (CPU) 166, which is operable with a memory 167 (e.g., non-volatile memory) and support circuits 168. The support circuits 168 are conventionally coupled to the CPU 166 and comprise cache, clock circuits, input/output subsystems, power supplies, and the like, and combinations thereof coupled to the various components of the substrate processing chamber 100 and the cleaning assembly 150.

In some embodiments, the CPU 166 is one of any form of general purpose computer processor used in an industrial setting, such as a programmable logic controller (PLC), for controlling various monitoring system component and sub-processors. The memory 167, coupled to the CPU 166, is non-transitory and is typically one or more of readily available memory such as random access memory (RAM), read only memory (ROM), floppy disk drive, hard disk, or any other form of digital storage, local or remote.

Herein, the memory 167 is in the form of a computer-readable storage media containing instructions (e.g., non-volatile memory), that when executed by the CPU 166, facilitates the operation of the substrate processing chamber 100 and the cleaning assembly 150. The instructions in the memory 167 are in the form of a program product such as a program that implements the methods of the present disclosure (e.g., middleware application, equipment software application etc.). The program code may conform to any one of a number of different programming languages. In one example, the disclosure may be implemented as a program product stored on computer-readable storage media for use with a computer system. The program(s) of the program product define functions of the embodiments (including the methods described herein).

Illustrative computer-readable storage media include, but are not limited to: (i) non-writable storage media (e.g., read-only memory devices within a computer such as CD-ROM disks readable by a CD-ROM drive, flash memory, ROM chips or any type of solid-state non-volatile semiconductor memory) on which information is permanently stored; and (ii) writable storage media (e.g., floppy disks within a diskette drive or hard-disk drive or any type of solid-state random-access semiconductor memory) on which alterable information is stored. Such computer-readable storage media, when carrying computer-readable instructions that direct the functions of the methods described herein, are embodiments of the present disclosure.

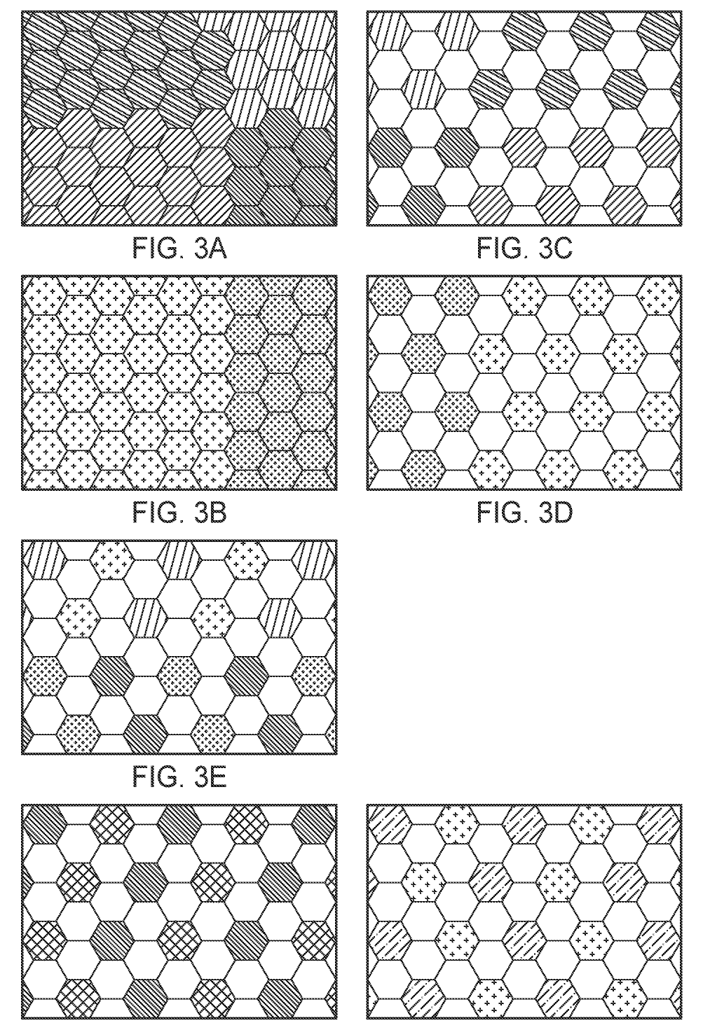

FIG. 2 depicts a schematic partial side view of the substrate suport 138 in accordance with at least one example of the present disclosure. The substrate support has an electrostatic chuck 201 having a body 202. In some embodiments, the body 202 includes a top segment 202A and a lower segment 202B. In some embodiments, the top segment 202A may include an oxide composition, as described below, in reference to FIG. 3. The oxide composition can include a dielectric composition. In one example, the top segment 202A includes an oxide composition including a binary composition and/or ternary metal oxide composition, as described below, in reference to FIG. 3. In some embodiments, the lower segment 202B includes a nitride composition.

The top segment 202A and the lower segment 202B are separated by a bond layer 210 In some embodiments, the bond layer 210 can include a thickness of about 0.02 mm to about 3 mm, e.g., about 0.1 mm to about 2.5 mm, about 0.5 mm to about 2 mm, about 1.0 mm to about 1.5 mm, or about 1.1 mm to about 1.4 mm. In some embodiments, the bond layer 210 can include a thermal conductivity of greater than 20 W/mK, e.g., about 20 W/mK about 30 W/mK, about 40 W/mK, about 50 W/mK, about 100 W/mK, or about 200 W/mK. In some embodiments, the bond layer 210 can include a coefficient of thermal expansion (CTE) of about 3 x 10⁻⁶ per Kelvin (/K) to about 10 x10⁻⁶/K, e.g., about 3 x 10⁻⁶/K to about 9 x 10⁻⁶/K, about 4 x 10⁻⁶/K to about 8 x 10⁻⁶/K or about 5 x 10⁻⁶/K to about 7 x 10⁻⁶/K. In some embodiments, the bond layer 210 can include a thermal shock resistance of about 400 °C to about 900 °C, e.g., about 400 °C to about 800 °C, about 500 °C to about 700 °C, or about 600 °C to about 650 °C.

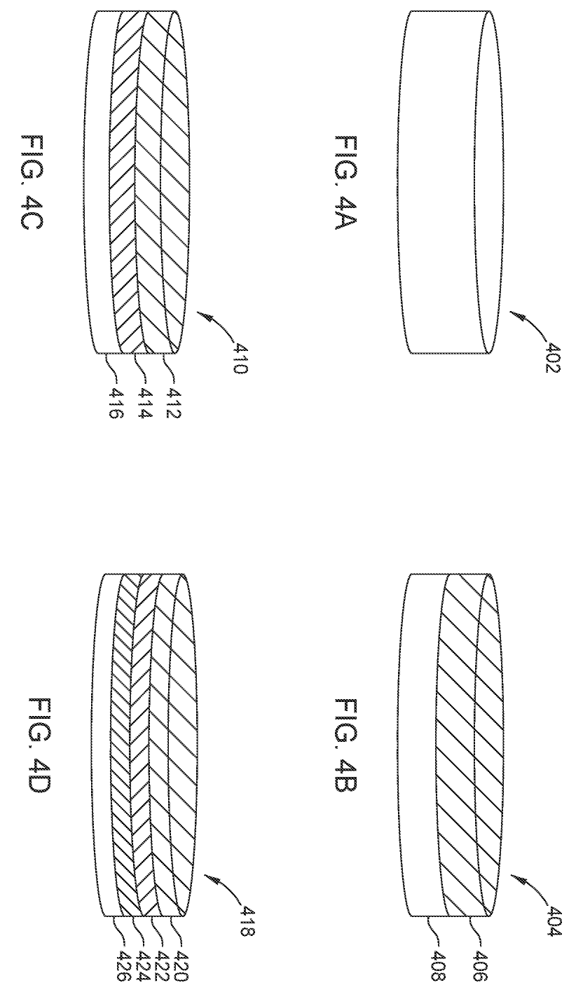

In some embodiments, the bond layer 210 can include an oxide composition. The oxide composition can include a mixture of the binary metal oxide composition and/or ternary metal oxide composition, and the nitride composition. In some embodiments, the bond layer 210 can include about 0 wt % to about 100 wt% of the oxide composition, and about 0 wt % to about 100 wt% of the nitride composition, as described below, in reference to FIGS. 4A-4D.

The body 202 includes a first side 216 configured to support the substrate 136136 and a second side 224 opposite the first side 216. The electrostatic chuck 201 has an outer diameter 255. The body 202 has an inner portion 281 and an outer portion 282, the inner portion 281 extending from the center of the electrostatic chuck 201 and the outer portion extending from the edge of the inner portion 281 to the outer diameter 255 and surrounding the inner portion 281. The substrate 136 is disposed in the inner portion 281 and an edge electrode is disposed on the outer portion 282. The body 202 thickness between the first side 216 and the second side 224 is between about 18 mm and 22 mm, such as about 20 mm.

The one or more chucking electrodes 254 are embedded in the inner portion 281 of the body 202 immediately adjacent to the first side 216. The chucking electrodes 254, when energized, electrostatically chuck the substrate 136 to the first side 216 of the electrostatic chuck 201. The one or more chucking electrodes 254 may be monopolar or bipolar. In some examples, the electrostatic chuck 201 provides Coulombic chucking. In some examples, the electrostatic chuck 201 provides Johnsen-Rahbek chucking.

Embedded below the chucking electrodes 254 is a mesh 290, e.g., a single continuous piece of woven conductive fibers, for example conductive wires, forming a mesh 290. The mesh 290 can be formed from a mesh sheet that is for example less than 0.1 to approximately 1.0 mm thick. The mesh is, for example, composed of a woven mat or sheet of individual nickel molybdenum wires, each wire having a thickness of diameter on the order of 0.05 to 1.0 mm or greater. The individual wires in the unitary mesh sheet comprise for example, a cross pattern, where one plurality of wire runs in a first direction and the second plurality runs in a second direction orthogonal to the first direction, and each wire extending in the first direction alternatingly crosses below a wire, then over the next wire, below the next wire, etc. of the second plurality of wires. Three sets of wire each set oriented with their lengths in one of a first, second and third direction may also be employed, where each of the first second and third directions are offset from one another by 60 degrees. Other patterns are also appropriate. The mesh 290 may be coupled to the bias power supply for biasing and shaping the plasma sheath or otherwise modifying the properties of a plasma in the processing volume adjacent to the outer circumference of the a substrate on the substrate receiving portion through a power supply connection, for example the aforementioned wire 292 (rod). The wire 292 is for example a solid Ni-Mo rod, for example 5 mm diameter. The mesh 290 can be configured to operate independently of the chucking electrodes 254. However, the chucking electrodes 254 may optionally be coupled to the bias power supply for shaping the plasma sheath in addition to the chucking power supply. A variable capacitor may be disposed between the bias power supply and the chucking electrodes 254 for isolating the chucking electrodes 254 from the mesh 290. In one example, the mesh 290 may be energized while the chucking electrodes 254 are de-energized. However, it should be appreciated that the chucking electrodes 254 may be energized at the same time the mesh 290 is energized or alternately while the mesh 290 is de-energized.

In some examples, RF energy supplied by the bias power supply may have a frequency of between about 350KHz to about 60MHz. In one example, the bias power supply is configured to generate the RF signal overlaid on a pulsed voltage signal of the negative pulsed DC power source. In one example, the voltage waveform of the negative pulsed DC power source may include a pulsed voltage signal range of about at 0.2Hz to about 20Hz with a duty cycle ranging from 10% to 100% overlaid with the RF signal of about 350KHz to about 60 Mhz. The negative pulsed DC power source is configured to provide a power profile to correct plasma sheath bending and maintain a substantially flat plasma sheath profile across the substrate 136.

The one or more heating elements 249 are embedded in the body 202 below the mesh 290. The heating elements 249 extend horizontally within the body 202 to between about 1.5 mm to about 3 mm from the outer diameter 255 of the body 202. In one example, the distance the heating elements 249 extend horizontally within the body 202 is about 2.5 mm from the outer diameter 255 of the body 202.

The heating elements 249 may be arranged in one or more zones to control a temperature of the electrostatic chuck 201. For example, the heating elements 249 may be arranged in one, two or four zones for supplying a temperature to the substrate 136. The heating elements 249 may have a hollow in the center of the diameter of the body 202 through which power supply wires may pass. The heating elements 249 are coupled to a power source, e.g., an AC power source, to power the heating elements 249. The one or more heating elements 249 are configured to supply a temperature to the substrate of about 200 °C to about 900 °C. For example, the electrostatic chuck 201 is configured to operate at temperatures exceeding 700 °C, such as about 750 °C.

The body 202 can include a top segment 202A and a lower segment 202B. In some embodiments, the top segment 202A can include an oxide composition, including at least an oxide composition. In some embodiments, the oxide composition can include a binary metal oxide including at least a first metal, as shown in FIG. 3A. In some embodiments, the first metal composition can include a rare earth metal, e.g., cerium, erbium, holmium, lanthanum, lutetium, scandium, samarium, terbium, yttrium, ytterbium, or a combination thereof. For example, the first metal composition can include cerium oxide, erbium oxide, holmium oxide, lanthanum oxide, lutetium oxide, scandium oxide, samarium oxide, terbium oxide, yttrium oxide, ytterbium oxide, or combinations thereof. Without being bound by theory, an oxide composition including a binary metal oxide can allow for chemical vapor deposition processes to be performed at temperatures of about 400 °C to about 800 °C, while still providing a resistivity of 1x10¹¹ Ω•cm to about 1x10⁸ Ω•cm.

In some embodiments, the oxide composition can include a ternary metal oxide including a first metal and a second metal, as shown in FIG. 3B. In some embodiments, the first metal can include a rare earth metal, e.g., cerium, erbium, holmium, lanthanum, lutetium, scandium, samarium, terbium, yttrium, ytterbium, or a combination thereof. In some embodiments, the second metal can include a rare earth metal, e.g., cerium, erbium, holmium, lanthanum, lutetium, scandium, samarium, terbium, yttrium, ytterbium, or a combination thereof. For example, the oxide composition can include cerium erbium oxide, cerium holmium oxide, cerium lanthanum oxide, cerium lutetium oxide, cerium scandium oxide, cerium samarium oxide, cerium terbium oxide, cerium yttrium oxide, cerium ytterbium oxide, or combinations. As a further example, the oxide composition can include erbium holmium oxide, erbium lanthanum oxide, erbium lutetium oxide, erbium scandium oxide, erbium samarium oxide, erbium terbium oxide, erbium yttrium oxide, erbium ytterbium oxide, or combinations. As a further example, the oxide composition can include holmium lanthanum oxide, holmium lutetium oxide, holmium scandium oxide, holmium samarium oxide, holmium terbium oxide, holmium yttrium oxide, holmium ytterbium oxide, or combinations. As a further example, the oxide composition can include lanthanum lutetium oxide, lanthanum scandium oxide, lanthanum samarium oxide, lanthanum terbium oxide, lanthanum yttrium oxide, lanthanum ytterbium oxide, or combinations. As a further example, the oxide composition can include lutetium scandium oxide, lutetium samarium oxide, lutetium terbium oxide, lutetium yttrium oxide, lutetium ytterbium oxide, or combinations. As a further example, the oxide composition can include scandium samarium oxide, scandium terbium oxide, scandium yttrium oxide, scandium ytterbium oxide, or combinations. As a further example, the oxide composition can include samarium terbium oxide, samarium yttrium oxide, samarium ytterbium oxide, or combinations. As a further example, the oxide composition can include terbium yttrium oxide, terbium ytterbium oxide, or combinations. As a further example, the oxide composition can include yttrium ytterbium oxide. Without being bound by theory, a oxide composition including a ternary metal composition can allow chemical vapor deposition processes to be performed at temperatures of about 400 °C to about 800 °C, while still providing a resistivity of 1x10¹¹ Ω•cm to about 1x10⁸ Ω•cm and high fluorine etch resistance.

In some embodiments, the first metal can include a Group 2-14 metal, e.g., barium, beryllium, calcium, hafnium, magnesium, niobium, strontium, tantalum, thallium, zirconium, or a combination thereof. In some embodiments, the second metal can include a Group 2-14 metal, e.g., aluminum, boron, chromium, iron, manganese, molybdenum, nickel, silicon, titanium, vanadium, or a combination thereof. For example, the ternary oxide composition can include magnesium vanadium oxide, hafnium aluminum oxide, strontium titanium oxide, or a combination thereof.

In some embodiments, the oxide composition can include a first binary metal composition and a second binary metal composition, as shown in FIG. 3C. In some embodiments, the first binary metal composition can include a Group 2-14 metal oxide, e.g., barium oxide, beryllium oxide, calcium oxide, hafnium oxide, magnesium oxide, niobium oxide, strontium oxide, tantalum oxide, thallium oxide, zirconium oxide, or a combination thereof. In some embodiments, the second binary metal composition can include a rare earth metal oxide, e.g., cerium oxide, erbium oxide, holmium, lanthanum, lutetium, scandium, samarium, terbium, yttrium, ytterbium, or a combination thereof. In some embodiments, the first metal composition may be present in the oxide composition at a weight percent of about 0.01 wt% to about 99.99 wt%, e.g., about 0.1 wt% to about 99.9 wt%, about 1 wt% to about 90 wt%, about 10 wt% to about 80 wt%, about 20 wt% to about 70 wt%, about 30 wt% to about 60 wt%, or about 40 wt% to about 50 wt%. In some embodiments, the second metal composition may be present in the oxide composition at a weight percent of about 0.01 wt% to about 99.99 wt%, e.g., about 0.1 wt% to about 99.9 wt%, about 1 wt% to about 90 wt%, about 10 wt% to about 80 wt%, about 20 wt% to about 70 wt%, about 30 wt% to about 60 wt%, or about 40 wt% to about 50 wt%. For example, the oxide composition can include about 40 wt% of the first binary metal composition and about 60 wt% of the second binary metal composition. Without being bound by theory, an oxide composition including a first binary metal composition and a second binary metal composition can allow for chemical vapor deposition processes to be performed at temperatures of about 500 °C to about 900 °C, while still providing a resistivity of 1x10¹¹ Ω•cm to about 1x10⁸ Ω•cm.

In some embodiments, the oxide composition can include a binary metal composition, e.g., a Group 2-14 metal oxide, and a ternary metal composition, e.g., a ternary metal oxide including a first metal such as barium, beryllium, calcium, hafnium, magnesium, niobium, strontium, tantalum, thallium, or zirconium, and a second metal such as aluminum, boron, chromium, iron, manganese, molybdenum, nickel, silicon, titanium, or vanadium, as shown in FIG. 3D. In some embodiments, the binary metal composition may be present in the oxide composition at a weight percent of about 0.1 wt% to about 99.9 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the ternary metal composition may be present in the oxide composition at a weight percent of about 0.1 wt% to about 99.9 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. For example, the oxide composition can include about 30 wt% of the binary metal composition and about 70 wt% of the ternary metal composition. Without being bound by theory, an oxide composition including a first binary metal composition and a second binary metal composition can allow for chemical vapor deposition processes to be performed at temperatures of about 500 °C to about 900 °C, while still providing a resistivity of 1x10¹¹ Ω•cm to about 1x10⁸ Ω•cm.

In some embodiments, the oxide composition can include a first binary metal composition, e.g., a Group 2-14 metal oxide, a second binary metal composition, e.g., a rare earth metal oxide, and a ternary metal composition, e.g., a ternary metal oxide including a first metal such as barium, beryllium, calcium, hafnium, magnesium, niobium, strontium, tantalum, thallium, or zirconium, and a second metal such as aluminum, boron, chromium, iron, manganese, molybdenum, nickel, silicon, titanium, or vanadium, as shown in FIG. 3E. In some embodiments, the first binary metal composition may be present in the oxide composition at a weight percent of about 0.1 wt% to about 99.9 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the second binary metal composition may be present in the oxide composition at a weight percent of about 0.1 wt% to about 99.9 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the ternary metal composition may be present in the oxide composition at a weight percent of about 0.1 wt% to about 99.9 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. For example, the oxide composition can include about 20 wt% of the first binary metal composition, about 60 wt% of the second binary metal composition, and about 20 wt% of the ternary metal composition. Without being bound by theory, a oxide composition including a first binary metal composition, a second binary metal composition, and a ternary metal oxide can allow chemical vapor deposition processes to be performed at temperatures of about 550 °C to about 950 °C, while still providing a resistivity of 1x10¹¹ Ω•cm to about 1x10⁸ Ω•cm and high fluorine etch resistance.

In some embodiments, the oxide composition can include a first binary metal composition, e.g., a Group 2-14 metal oxide, a second binary metal composition, e.g., a rare earth metal oxide, and a complex metal composition, e.g., a ternary metal oxide including one or more rare earth metals, e.g., cerium, erbium, holmium, lanthanum, lutetium, scandium, samarium, terbium, yttrium, ytterbium, and a Group 2-14 metal such as aluminum, boron, chromium, iron, manganese, molybdenum, nickel, silicon, titanium, or vanadium, as shown in FIG. 3F. In some embodiments, the first binary metal composition may be present in the oxide composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the second binary metal composition may be present in the oxide composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the complex metal composition may be present in the oxide composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. For example, the oxide composition can include about 60 wt% of the first binary metal composition, about 20 wt% of the second binary metal composition, and about 20 wt% of the complex metal composition. Without being bound by theory, a oxide composition including a first binary metal composition, a second binary metal composition, and a complex oxide can allow chemical vapor deposition processes to be performed at temperatures of about 550 °C to about 950 °C, while still providing a resistivity of 1x10¹¹ Ω•cm to about 1x10⁸ Ω•cm, and a high fluorine etch resistance.

In some embodiments, the oxide composition can include a binary metal composition, e.g., a Group 2-14 metal oxide, a ternary metal composition, e.g., a ternary metal oxide including a first metal such as barium, beryllium, calcium, hafnium, magnesium, niobium, strontium, tantalum, thallium, or zirconium, and a second metal such as aluminum, boron, chromium, iron, manganese, molybdenum, nickel, silicon, titanium, or vanadium, and a complex metal composition, e.g., a ternary metal oxide including one or more rare earth metals, e.g., cerium, erbium, holmium, lanthanum, lutetium, scandium, samarium, terbium, yttrium, ytterbium, and a Group 2-14 metal such as aluminum, boron, chromium, iron, manganese, molybdenum, nickel, silicon, titanium, or vanadium, as shown in FIG. 3G. In some embodiments, the binary metal composition may be present in the oxide composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the first ternary metal composition may be present in the oxide composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. In some embodiments, the complex metal composition may be present in the oxide composition at a weight percent of about 0.1 wt% to about 99.5 wt%, e.g., about 1 wt% to about 90 wt%, about 10 wt% to about 80 wt%, about 20 wt% to about 70 wt%, about 30 wt% to about 60 wt%, or about 40 wt% to about 50 wt%. For example, the oxide composition can include about 10 wt% of the first binary metal composition, about 500 wt% of the second binary metal composition, and about 40 wt% of the complex metal composition. Without being bound by theory, a oxide composition including a binary metal composition, a ternary metal composition, and a complex oxide can allow chemical vapor deposition processes to be performed at temperatures of about 550 °C to about 950 °C, while still providing a resistivity of 1x10¹¹ Ω•cm to about 1x10⁸ Ω•cm, and a high fluorine etch resistance.

In some embodiments, the lower segment 202B includes a nitride composition. The nitride composition can include a binary nitride composition, e.g., aluminum nitride, and a binary metal oxide composition, ternary metal oxide composition, or complex metal composition. In some embodiments, the binary nitride composition may be present in the nitride composition at a weight percent of about 85 wt% to about 100 wt%, e.g., about 85 wt% to about 99 wt%, about 88 wt% to about 95 wt%, about 90 wt% to about 94 wt%, or about 91 wt% to about 92 wt%. In some embodiments, the binary metal oxide composition, ternary metal oxide composition, or complex metal composition may be present in the nitride composition at a weight percent of about 0 wt% to about 15 wt%, e.g., about 0 wt% to about 12 wt%, about 0 wt% to about 10 wt%, about 2 wt% to about 8 wt%, or about 5 wt% to about 7 wt%.

The top segment 202A and the lower segment 202B are separated by a bond layer 210 formed from a bond layer composition. The bond layer 210 can include a mixture of the oxide composition and the nitride composition. In some embodiments, the bond layer 210 can include a mono-layer 402 including about 0 wt % to about 100 wt% of the oxide composition and about 0 wt % to about 100 wt% of the nitride composition, as shown in FIG. 4A. In some embodiments, the bond layer composition can include a bi-layer 404 including a first layer 406 having about 20 wt % to about 100 wt% of the oxide composition and about 0 wt % to about 80 wt% of the nitride composition. The bi-layer 404 includes a second layer 408 having about 0 wt % to about 80 wt% of the oxide composition and about 20 wt % to about 100 wt% of the nitride composition, as shown in FIG. 4B.

In some embodiments, the bond layer 210 can include a tri-layer 410 including a first layer 412 having about 40 wt% to about 100 wt% of the oxide composition and about 0 wt % to about 60 wt% of the nitride composition. The tri-layer 410 includes a second layer 414 having about 20 wt % to about 80 wt% of the oxide composition and about 20 wt % to about 80 wt% of the nitride composition. The tri-layer 410 includes a third layer 416 having about 0 wt % to about 60 wt% of the oxide composition and about 40 wt % to about 100 wt% of the nitride composition, as shown in FIG. 4C. In some embodiments, the bond layer 210 can include a tetra-layer 418 including a first layer 420 having about 60 wt % to about 100 wt% of the oxide composition and about 0 wt % to about 40 wt% of the nitride composition. The tetra-layer 418 includes a second layer 422 having about 40 wt % to about 80 wt% of the oxide composition and about 20 wt % to about 60 wt% of the nitride composition. The tetra-layer 418 includes a third layer 424 having about 20 wt % to about 60 wt% of the oxide composition and about 40 wt % to about 80 wt% of the nitride composition. The tetra-layer 418 includes a fourth layer 426 having about 0 wt % to about 40 wt% of the oxide composition and about 60 wt % to about 100 wt% of the nitride composition, as shown in FIG. 4D.

While not shown in FIGS. 4A-4D, the bond layer 210 can have any number of layers including a changing concentration gradient of the oxide composition and the nitride composition such that a greater concentration of oxide composition exists proximal to the top segment 202A, and a greater concentration of nitride composition exists towards the lower segment 202B. In some embodiments, the concentration gradient of the of the oxide composition, and the nitride composition may be continuous. Without being bound by theory, a concentration gradient of the oxide composition and the nitride composition may allow for increased adhesion between the top segment 202A and the lower segment 202B, thereby reducing the potential for delamination and/or cracking between the top segment 202A and the lower segment 202B. Additionally, and without being bound by theory, the increased adhesion between the top segment 202A and the lower segment 202B may allow for chemical vapor deposition processes to be performed at increased temperatures, e.g., about 400 °C to about 900 °C, while maintaining fluorine plasma resistivity.

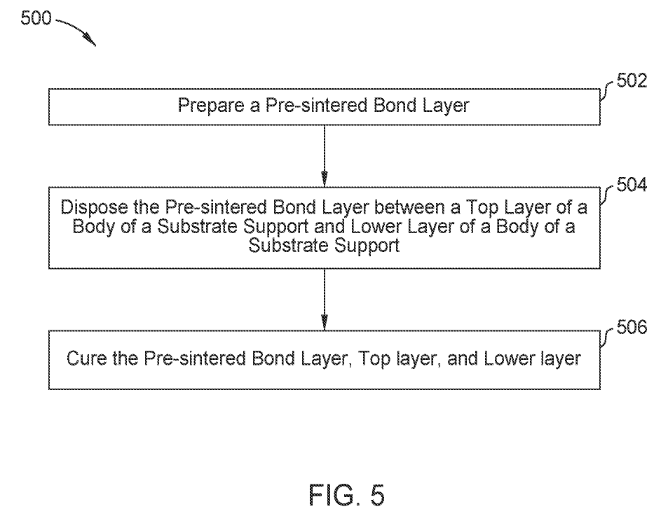

Now referring to FIG. 5 a method 500 for forming a substrate support is shown. At operation 502, a pre-sintered bond layer including the oxide composition, and the nitride composition is prepared. In some embodiments, each pre-sintered bond layer can have a thickness of about 20 µm to about 3 mm, e.g., about 20 µm to about 1 mm, about 50 µm to about 500 µm, or about 50 µm to about 100 µm. In some embodiments, the pre-sintered bond layer can be prepared via powder preparation. For example, one or more ceramic powders may be mixed with a polymer binder to form a mixture. The mixture may be pressed via uniaxial pressing and/or isostatic machining. The mixture may be green machined and the polymer binder may be removed from the mixture. The mixture may then be pre-sintered and green machine to form the pre-sintered bond layer.

In some embodiments, the pre-sintered bond layer can be prepared via powder slurry preparation. For example, one or more ceramic powders may be mixed with a polymer binder and a plasticizer in a solution to form a mixture. The mixture may be cast using a tape casting process. The cast mixture may be cut and laminated. The binder may be removed from the cut laminated sheets, in which the sheets may be pre-sintered and green machined to form the pre-sintered bond layer.

In some embodiments, the pre-sintered bond layer can be prepared via powder gel preparation. For example, one or more ceramic powders may be mixed with a gelling agent to form a mixture. The mixture may be cast using a gel casting process. The cast may be green machined and the polymer binder may be removed from the cast. The cast may then be pre-sintered and green machined to form the pre-sintered bond layer. In some embodiments the pre-sintered bond layer can be prepared via one or more 3-D printing processes.

At operation 504, the pre-sintered bond layer is disposed between a top segment 202A of the electrostatic chuck 201 and a lower segment 202B of the electrostatic chuck. In some embodiments, the pre-sintered bond layer may be disposed and pressed between the top segment 202A and the lower segment 202B. In some embodiments, the pre-sintered bond layer may be pressed at a pressure of about 10 MPa to about 40 MPa, e.g., about 10 MPa to about 38 MPa, about 15 MPa to about 35, or about 20 MPa to about 30 MPa. In some embodiments, the pre-sintered bond layer may be pressed when operating at a temperature of about 1400 ˚C to about 1900 ˚C, e.g., about 1400 ˚C to about 1800 ˚C, 1500 ˚C to about 1700 ˚C, 1600 ˚C to about 1700 ˚C.

At operation 506, the electrostatic chuck 201 having the pre-sintered bond layer disposed between the top segment 202A and the lower segment 202B is cured to form the bond layer 210. In some embodiments, curing can include co-firing the top segment 202A, the lower segment 202B, and the pre-sintered bond layer via hot pressing according to one or more hot pressing parameters described herein. In some embodiments, curing can include co-firing the top segment 202A, the lower segment 202B, and the pre-sintered bond layer via hot isostatic pressing according to one or more hot isostatic pressing parameters described herein. Without being bound by theory, by co-firing the top segment 202A, the lower segment 202B, and the pre-sintered bond layer concurrently can prevent delamination and/or cracking between each of the top segment 202A, the lower segment 202B, and the bond layer 210.

Overall, the oxide compositions of the present disclosure can increase the longevity of the ceramic component, e.g., a substrate support, heater, and/or electrostatic chuck, due to the increased chemical compatibility between the oxide top segment and the cleaning plasma chemistry. The oxide top segment can be secured to the nitride lower segment via the bond layer, in which the bond layer can increase the longevity of the ceramic component, e.g., a substrate support, heater, and/or electrostatic chuck, due to the increased thermomechanical compatibility between the top segment of the substrate support and the lower segment of the substrate support, thereby reducing the delamination and/or cracking.

As used herein, the term “proximal”, refers to a location that is adjacent to and/or near to a point of reference such as an origin or a point of attachment, e.g., a distance of about 0 mm to about 10 mm, e.g., about 0 mm to about 9 mm, about 1 mm to about 8 mm, about 1 mm to about 5 mm, or about 2 mm to about 4 mm. For example, the heating elements may be proximal to the support shaft, in which the heating elements are disposed near and/or adjacent to the support shaft.

Although the present disclosure mainly describes substrate supports (e.g., heaters and/or electrostatic chucks), the methods and apparatus can be more generally applied to other components used in process chambers, such as showerheads or other components that are exposed to harsh process conditions.

It is contemplated that one or more aspects disclosed herein may be combined. Moreover, it is contemplated that one or more aspects disclosed herein may include some or all of the aforementioned benefits.

While the foregoing is directed to embodiments of the present disclosure, other and further embodiments of the disclosure may be devised without departing from the basic scope thereof.

What is claimed is:

1. A substrate support for disposition in a processing chamber, the substrate support comprising:
a body having a top segment comprising an oxide composition and a lower segment comprising a nitride composition;
one or more chucking electrodes embedded in the top segment;
a mesh embedded in the lower segment;
one or more heating elements disposed below the mesh proximal to a support shaft; and
a bond layer disposed between the top segment and the lower segment.

2. The substrate support of claim 1, wherein the bond layer comprises a mixture of:
the oxide composition, wherein the oxide composition comprises a binary metal oxide composition, a ternary metal oxide composition, or a complex metal composition; and
the nitride composition.

3. The substrate support of claim 2, wherein the binary metal oxide composition comprises:
a rare earth metal comprising cerium, erbium, holmium, lanthanum, lutetium, scandium, samarium, terbium, yttrium, ytterbium, or
a Group 2-14. metal comprising barium, beryllium, calcium, hafnium, magnesium, niobium, strontium, tantalum, thallium, zirconium.

4. The substrate support of claim 2, wherein the ternary metal oxide composition comprises:
a first metal comprising cerium, erbium, holmium, lanthanum, lutetium, scandium, samarium, terbium, yttrium, ytterbium, barium, beryllium, calcium, hafnium, magnesium, niobium, strontium, tantalum, thallium, or zirconium; and
a second metal comprising cerium, erbium, holmium, lanthanum, lutetium, scandium, samarium, terbium, yttrium, ytterbium, aluminum, boron, chromium, iron, manganese, molybdenum, nickel, silicon, titanium, or vanadium.

5. The substrate support of claim 2, wherein the nitride composition comprises:
a binary nitride composition; and
the binary metal oxide composition.

6. The substrate support of claim 2, wherein the bond layer comprises a mono-layer comprising about 0 wt % to about 100 wt% of the oxide composition and about 0 wt % to about 100 wt% of the nitride composition.

7. The substrate support of claim 2, wherein the bond layer comprises a bi-layer comprising
a first layer comprising about 20 wt % to about 100 wt% of the oxide composition and about 0 wt % to about 80 wt% of the nitride composition; and
a second layer comprising about 0 wt % to about 80 wt% of the oxide composition and about 20 wt % to about 100 wt% of the nitride composition.

8. The substrate support of claim 2, wherein the bond layer comprises a tri-layer comprising
a first layer comprising about 40 wt % to about 100 wt% of the oxide composition and about 0 wt % to about 60 wt% of the nitride composition;
a second layer comprising about 20 wt % to about 80 wt% of the oxide composition and about 20 wt % to about 80 wt% of the nitride composition; and
a third layer comprising about 0 wt % to about 60 wt% of the oxide composition and about 40 wt % to about 100 wt% of the nitride composition.

9. The substrate support of claim 2, wherein the bond layer comprises a tetra-layer comprising
a first layer comprising about 60 wt % to about 100 wt% of the oxide composition and about 0 wt % to about 40 wt% of the nitride composition;
a second layer comprising about 40 wt % to about 80 wt% of the oxide composition and about 20 wt % to about 60 wt% of the nitride composition;
a third layer comprising about 20 wt % to about 60 wt% of the oxide composition and about 40 wt % to about 80 wt% of the nitride composition; and
a fourth layer comprising about 0 wt % to about 40 wt% of the oxide composition and about 60 wt % to about 100 wt% of the nitride composition.

10. A substrate support for disposition in a processing chamber, the substrate support comprising:
a body having a top segment comprising an oxide composition and a lower segment comprising a nitride composition;
one or more chucking electrodes embedded in the top segment;
a mesh embedded in the lower segment;
one or more heating elements disposed below the mesh proximal to a support shaft; and
a bond layer disposed between the top segment and the lower segment, wherein the bond layer comprises a mixture.

11. The substrate support of claim 10, wherein the mixture comprises:
the oxide composition, wherein the oxide composition comprises a binary metal oxide composition, a ternary metal oxide composition, or a complex metal composition; and
the nitride composition.

12. The substrate support of claim 11, wherein the binary metal oxide composition comprises:
a rare earth metal comprising cerium, erbium, holmium, lanthanum, lutetium, scandium, samarium, terbium, yttrium, ytterbium; or
a Group 2-14. metal comprising barium, beryllium, calcium, hafnium, magnesium, niobium, strontium, tantalum, thallium, zirconium.

13. The substrate support of claim 11, wherein the ternary metal oxide composition comprises:
a first metal comprising cerium, erbium, holmium, lanthanum, lutetium, scandium, samarium, terbium, yttrium, ytterbium, barium, beryllium, calcium, hafnium, magnesium, niobium, strontium, tantalum, thallium, or zirconium; and
a second metal comprising cerium, erbium, holmium, lanthanum, lutetium, scandium, samarium, terbium, yttrium, ytterbium, aluminum, boron, chromium, iron, manganese, molybdenum, nickel, silicon, titanium, or vanadium.

14. The substrate support of claim 11, wherein the nitride composition comprises:
a binary nitride composition; and
the binary metal oxide composition.

15. The substrate support of claim 11, wherein the bond layer comprises a mono-layer comprising about 0 wt % to about 100 wt% of the oxide composition and about 0 wt % to about 100 wt% of the nitride composition.

16. The substrate support of claim 11, wherein the bond layer comprises a bi-layer comprising
a first layer comprising about 20 wt % to about 100 wt% of the oxide composition and about 0 wt % to about 80 wt% of the nitride composition; and
a second layer comprising about 0 wt % to about 80 wt% of the oxide composition and about 20 wt % to about 100 wt% of the nitride composition.

17. The substrate support of claim 11, wherein the bond layer comprises a tri-layer comprising
a first layer comprising about 40 wt % to about 100 wt% of the oxide composition and about 0 wt % to about 60 wt% of the nitride composition;
a second layer comprising about 20 wt % to about 80 wt% of the oxide composition and about 20 wt % to about 80 wt% of the nitride composition; and
a third layer comprising about 0 wt % to about 60 wt% of the oxide composition and about 40 wt % to about 100 wt% of the nitride composition.

18. The substrate support of claim 11, wherein the bond layer comprises a tetra-layer comprising
a first layer comprising about 60 wt % to about 100 wt% of the oxide composition and about 0 wt % to about 40 wt% of the nitride composition;
a second layer comprising about 40 wt % to about 80 wt% of the oxide composition and about 20 wt % to about 60 wt% of the nitride composition;
a third layer comprising about 20 wt % to about 60 wt% of the oxide composition and about 40 wt % to about 80 wt% of the nitride composition; and
a fourth layer comprising about 0 wt % to about 40 wt% of the oxide composition and about 60 wt % to about 100 wt% of the nitride composition.

19. A method of forming a substrate support, the method comprising:
preparing a pre-sintered bond layer comprising an oxide composition and a nitride composition;
disposing the pre-sintered bond layer between a top segment of a body of the substrate support and a lower segment of the body; and
cure the pre-sintered bond layer, the top segment of the body, and the lower segment of the body.

20. The method of claim 19, wherein curing the pre-sintered bond layer, the top segment of the body, and the lower segment of the body comprises co-firing the pre-sintered bond layer, the top segment of the body, and the lower segment.
